(19) United States
(12) Patent Application Publication
(10) Pub. No.: US 2012/0235002 A1
(43) Pub. Date: Sep. 20, 2012

(54) MOUNTING APPARATUS

(75) Inventors: GUANG-YI ZHANG, Shenzhen City (CN); WEI QIU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/217,292

(22) Filed: Aug. 25, 2011

(30) Foreign Application Priority Data
Mar. 15, 2011 (CN) 201110061996.3

(51) Int. Cl. H05K 7/00

(52) U.S. Cl. 248/309.1

(57) ABSTRACT

A mounting apparatus includes a tray, a mounting member, a latch member, and a locking member. The tray can receive a data storage device. The mounting member mount is mounted to the tray, and a chamber is defined in the mounting member. The latch member pivotally engages to the mounting member, and includes a latch and a hook. The locking member is received in the chamber, the locking member includes a sliding member, a pivot member, and a first resilient member. The pivot member is pivotally engaged with the mounting member, and is slidably engaged with the sliding member. The sliding member is capable of sliding along the chamber, and engages with the first resilient member.

### BACKGROUND

1. Technical Field

The present disclosure relates to a mounting apparatus, and particularly, to a mounting apparatus for a computer.

2. Description of Related Art

Hard drives and optical drives are often received in a mounting apparatus to be quickly installed in a computer. The mounting apparatus are is to a computer case by latches, and the latches can be unlocked by pushing a button on the mounting apparatus. However, the latches may be inadvertently unlocked when the button is accidentally touched.

Therefore, what is needed is a mounting apparatus that overcomes the above-mentioned problem.

### BRIEF DESCRIPTION OF THE DRAWINGS

The components in the drawings are not necessarily drawn to scale, the emphasis instead being placed upon clearly illustrating the principles of a mounting apparatus. Moreover, in the drawings, like reference numerals designate corresponding parts throughout the several views.

FIG. 1 is an isometric, exploded view of an exemplary embodiment of a mounting apparatus.

FIG. 2 is a view similar to FIG. 1, but showing another aspect of the mounting apparatus.

FIG. 3 is an assembled view of the mounting apparatus of FIG. 1, showing a locking member in an unlocked position.

FIG. 4 is a cross section of FIG. 3, taken along line IV-IV thereof.

FIG. 5 is an assembled view of the mounting apparatus of FIG. 1, showing the locking member located between the unlocked position and a locked position.

FIG. 6 is a cross section of FIG. 5, taken along line VI-VI thereof.

FIG. 7 is an assembled view of the mounting apparatus of FIG. 1, showing the locking member in the locked position.

FIG. 8 is a cross section view of FIG. 7, taken along line VIII-VIII thereof.

### DETAILED DESCRIPTION

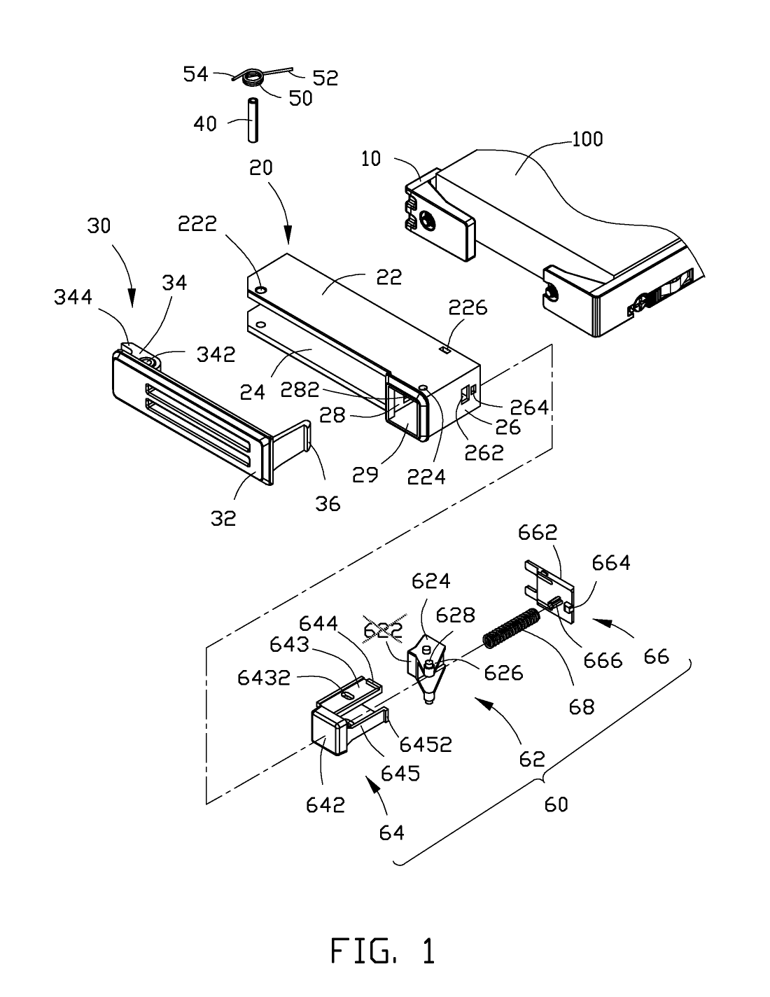

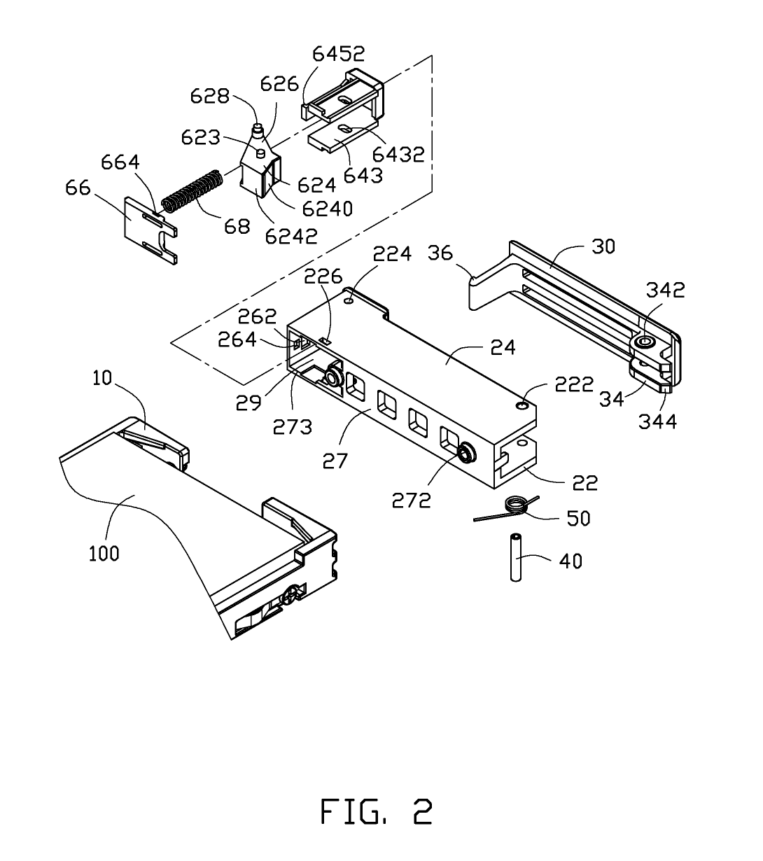

Referring to FIG. 1-2, an exemplary embodiment of a mounting apparatus includes a tray 10 to hold a data storage device 100, a mounting member 20 mounted to the tray 10, a latch member 30 pivotally engaged with the mounting member 20, a dowel pin or hinge rod (pole 40), a first resilient member 50, and a locking member 60 to lock the latch member 30.

The mounting member 20 includes a top plate 22, a bottom plate 24, a side plate 26, and a back plate 27. The back plate 27 defines two mounting holes 272 therein. A blocking plate 28, in parallel with the side plate 26, is arranged between the top plate 22 and the bottom plate 24, and a chamber 29 is formed in between the top plate 22, the bottom plate 24, the side plate 26, and the blocking plate 28. The back plate 27 defines an opening 273 communicating with the chamber 29. The blocking plate 28 defines a passage 282. Two first spindle holes 222 are defined, one on the left side of the top plate 22 and the other on the left side of the bottom plate 24. Two pivot holes 224 are defined, one on the right side of the top plate 22 and the other on the right side of the bottom plate 24. Two first fixing holes 226 are defined, one on the rear right side of the top plate 22 and the other on the rear right side of the bottom plate 24. A second fixing hole 264 and a retaining hole 262 are defined on the rear side of the side plate 26, and the retaining hole 262 is defined in front of the second fixing hole 264.

The latch member 30 includes a front plate 32, and two spindle parts 34 and a hook 36 are respectively arranged on the left side and the right side of the front plate 32. Each spindle part 34 defines a second spindle hole 342 therein, and a latch 344 is arranged on each spindle part 34.

The first resilient member 50 includes a first end 52 and a second end 54.

The locking member 60 includes a pivot member 62, a sliding member 64, a fixing member 66, and a second resilient member 68. In the present embodiment, the second resilient member 68 is a compression spring.

Two sliding pins 623 are arranged on an upper surface and a lower surface of the pivot member 62. A blocking part 624 extends from the pivot member 62, and the blocking part 624 includes a bevel sliding surface 6240 and a blocking surface 6242. Two pivot parts 626 extend from the upper surface and the lower surface of the pivot member 62, and a pivot pin 628 extends from each of the pivot parts 626.

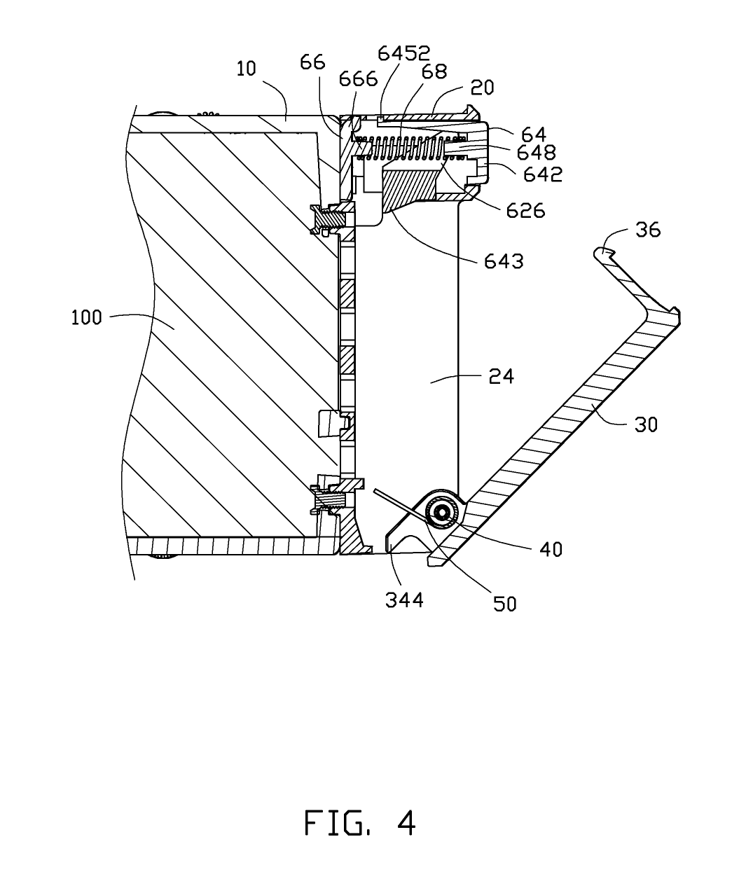

The sliding member 64 includes a button plate 642. Two first sliding plates 643 extend from a top side a bottom side of the button plate 642, and a second sliding plate 645 extends from a right side of the button plate 642. A first pillar 648 (FIG. 4) extends from the center of a rear side of the button plate 642. Two sliding ditches 6432 are oppositely defined in the two first sliding plates 643. A first retaining tab 644 is arranged on each of the first sliding plates 643, and a second retaining tab 6452 is arranged on the second sliding plate 645.

The fixing member 66 includes a fixing plate 662, and three fixing tabs 664 are arranged on the fixing plate 662 in accordance with the two first fixing holes 226 and the second fixing hole 264 of the mounting member 20. A second pillar 666 is arranged in the center of the fixing plate 662.

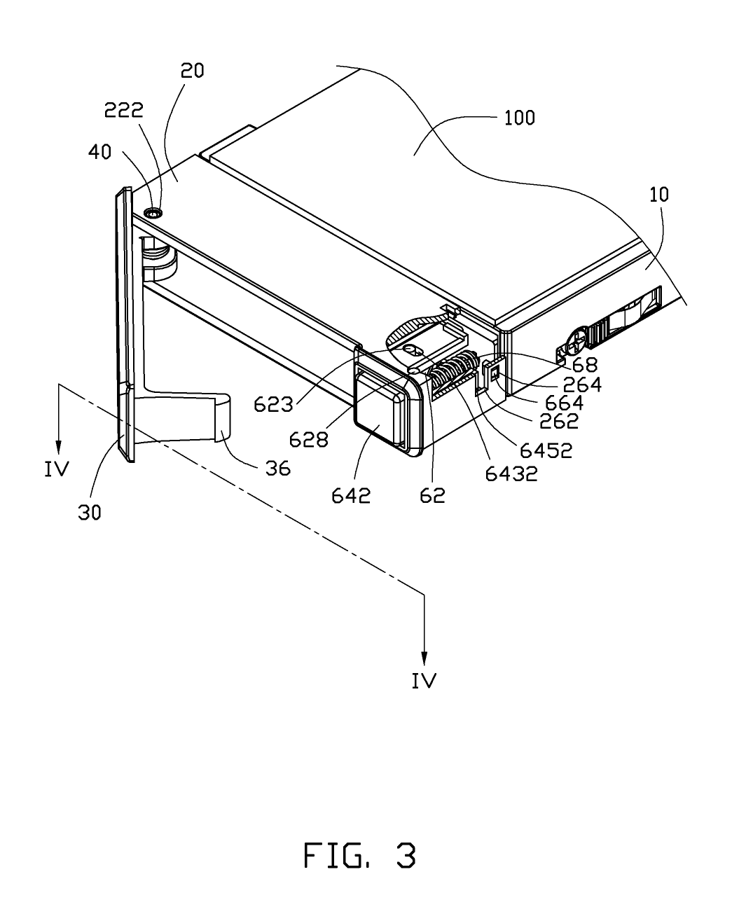

Referring to FIG. 3-4, when assembling the mounting apparatus, the pivot member 62 engages with the sliding member 64, and the two sliding pins 623 of the pivot member 62 are slidably engaged with the sliding ditches 6432 of the two first sliding plates 643, respectively. The two pivot pins 628 of the pivot member 62 are exposed from the sliding member 64. The sliding member 64 and the pivot member 62 are arranged in the chamber 29 of the mounting member 20 through the opening 273 of the back plate 27. The two pivot pins 628 of the pivot member 62 are pivotally engaged in the pivot holes 224 of the mounting member 20; the second retaining tab 6452 of the second sliding plate 645 is slidably engaged to the retaining hole 262, and the sliding member 64 can move back and forth in the chamber 29 of the mounting member 20. The first retaining tabs 644 of the sliding member 64 are blocked by retaining parts (not shown) arranged in the top plate 22 and the bottom plate 24 to prevent the sliding member 64 sliding out of the mounting member 20. The second resilient member 68 passes between the two pivot parts 626 of the pivot member 62, and one end of the second resilient member 68 is engaged with the first pillar 648 of the sliding member 64. The three fixing tabs 664 of the fixing member 66 are engaged with the corresponding first fixing holes 226 and the second fixing hole 264 of the mounting member 20, and the second pillar 666 of the fixing member 66 is engaged with the other end of the second resilient member 68. The second resilient member 68 pushes the sliding member 64 forward to force the rear side of the two sliding ditches 6432 of the sliding member 64 to push the sliding pins of the pivot member 62 toward the left side of the sliding ditches 6432. This forces the blocking part 624 to pivot around the pivot holes 224 of the mounting member 20 toward the blocking plate 28 of the mounting member 20, and it is thus exposed from the chamber 29 through the passage 282 of the blocking plate 28. The second retaining tabs 6452 slide forward in the retaining hole 262.

The first resilient member 50 is arranged between the two second spindle holes 342 of the latch member 30, and the second spindle holes 342 are aligned with the first spindle holes 222 of the mounting member 20. The pole 40 penetrates through the two first spindle holes 222, the second spindle holes 342, and the first resilient member 50 to pivotally fix the latch member 30 to the mounting member 20; the first end 52 and the second end 54 of the first resilient member 50 abut the mounting member 20 and the latch member 30, respectively. In the present embodiment, the first resilient member 50 is a torsion spring. The mounting member 20 is mounted to the tray 10 with fasteners (not shown) which penetrate through the mounting holes 272 of the mounting member 20.

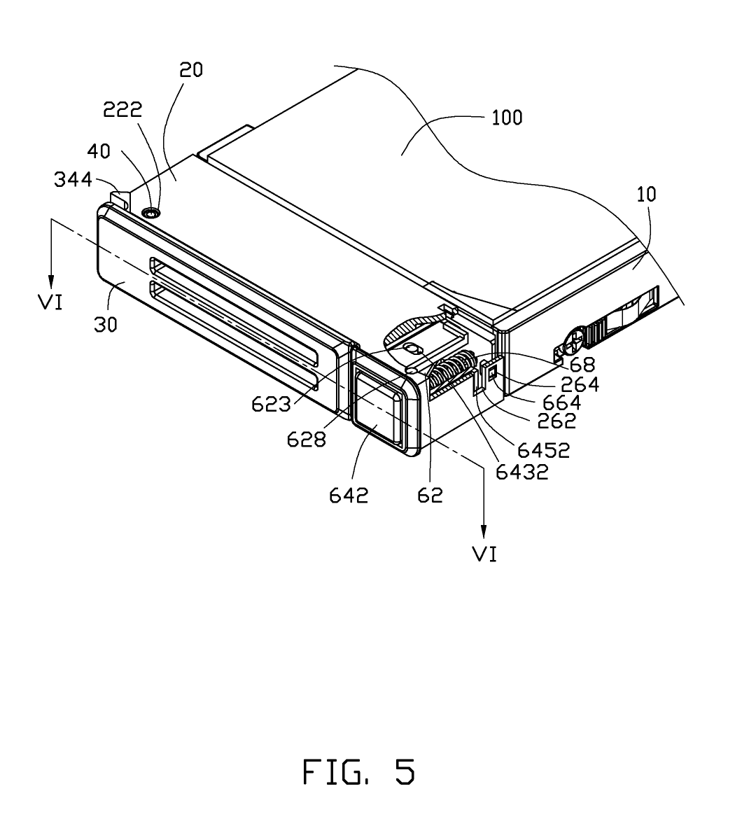

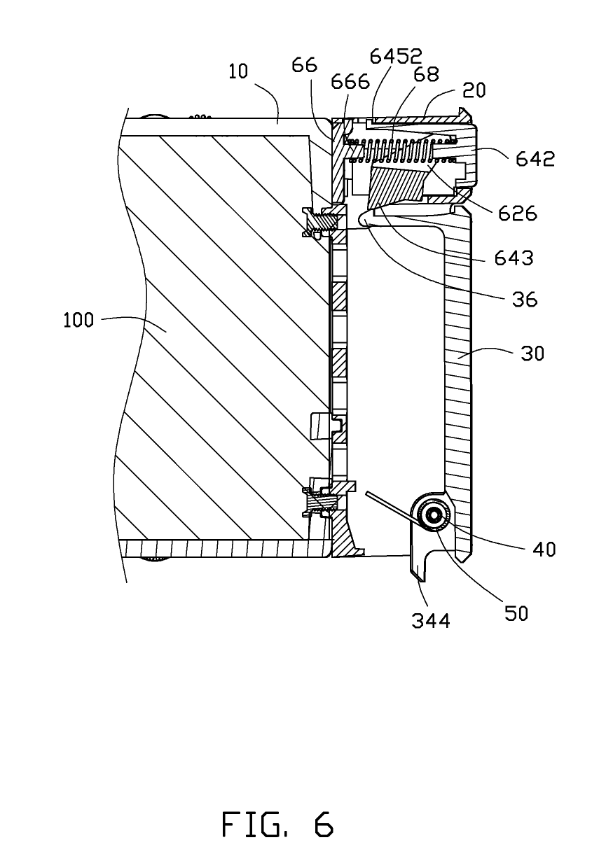

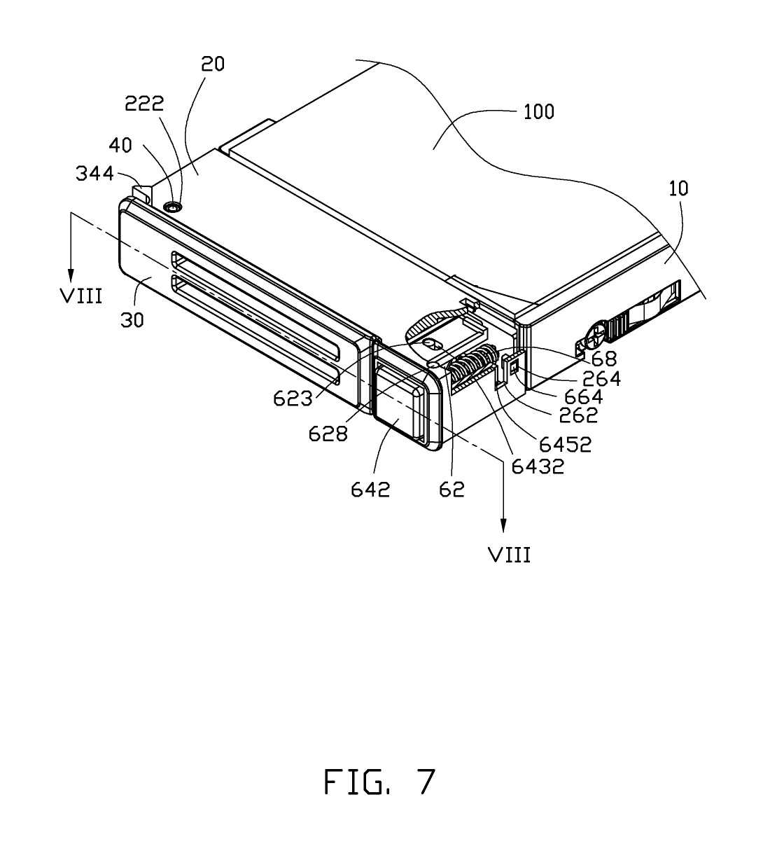

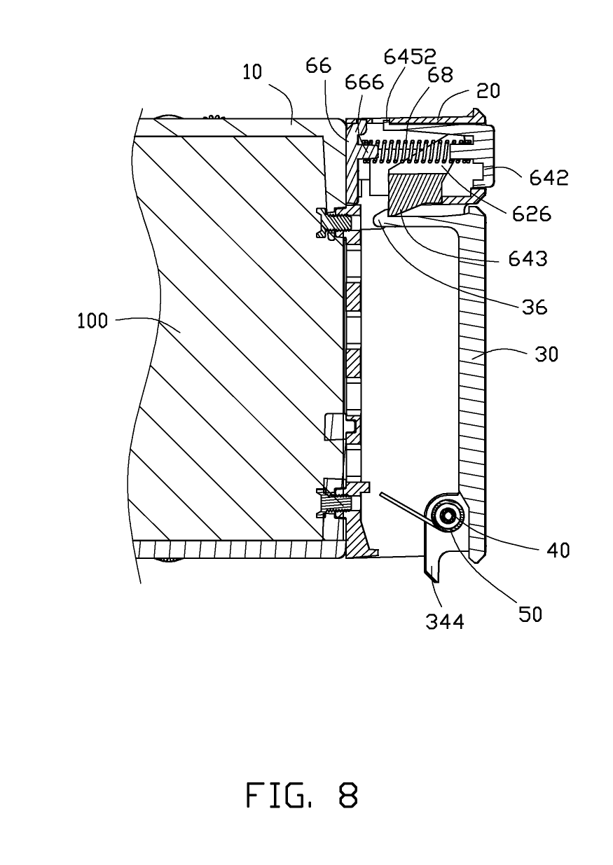

Referring to FIG. 5-8, when installing the mounting apparatus to a computer case (not shown), the tray 10, the mounting member 26, and the latch member 30 are inserted into the computer case. The latch member 30 pivots around the pole 40 toward the mounting member 20, and the first resilient member 50 is elastically deformed. The hook 36 of the latch member 30 abuts the sliding surface 6240 of the blocking part 624 of the pivot member 62 exposed from the chamber 29 through the passage 282, and forces the blocking part 624 of the pivot member 62 to pivot around the pivot holes 224 away from the blocking plate 28 of the mounting member 20. The sliding pins 623 of the pivot member 62 slide toward the right side of the sliding ditches 6432, and push the sliding member 64 backwards; the sliding member 64 thus compresses the second resilient member. When the hook 36 of the latch member 30 passes though the sliding surface 6240 of the blocking part 624, the second resilient member 68 is released and pushes the sliding member 64 forwards, and the blocking part 624 pivots around the pivot hole toward the blocking plate 28 to block the hook 36 with the blocking surface 6242. The latches 344 of the latch member 30 are exposed on the left side of the mounting member 20, and engage the computer case so as to mount the mounting apparatus onto the computer case.

When disassembling the mounting apparatus from the computer case, the button plate 642 of the sliding member 64 is pushed toward the data storage device 100 to force the sliding member 64 to slide backwards, and the second resilient member 68 is compressed. The front side of the sliding ditches 6432 of the sliding member 64 pushes the sliding pins 623 of the pivot member 62 toward the right side of the sliding ditches 6432, and the blocking part 624 of the pivot member 62 pivots around the pivot holes 224 away from the blocking plate 28. The blocking surface 6242 pushes against the hook 36 while pivoting, and release the hook 36 after the blocking surface 6242 has disengaged from the hook 36. The first resilient member 50 is released and forces the latch member 30 to pivot around the pole 40 away from the mounting member 20, and the latches 344 are received in the mounting member 20 to allow the mounting apparatus to be disassembled from the computer case. Since the blocking surface 6242 pushes the hook backwards before the hook is released, any inadvertent unlocking of the locking member 60 is prevented.

In other embodiments, the second resilient member 68 can engage to the tray 10 without using the fixing member 66.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A mounting apparatus, comprising:
a tray to receive a data storage device;
a mounting member mounted to the tray, wherein the mounting member defines a chamber therein;
a latch member pivotally engaged to the mounting member, wherein the latch member comprises a latch and a hook ; and
a locking member received in the chamber, wherein the locking member comprises a sliding member, a pivot member, and a first resilient member; the pivot member is pivotally engaged with the mounting member, and slidably engaged with the sliding member; the sliding member is capable of sliding along the chamber, and is engaged with the first resilient member; the pivot member pivots in a first direction to engage with the hook or in a second direction to disengage from the hook; the sliding member slides in a third direction when the pivot member pivots in the first direction, and the sliding member slides in a fourth direction when the pivot member pivots in the second direction; the mounting apparatus is locked to a computer case when the hook is engaged with the pivot member.

2. The mounting apparatus as claimed in claim 1, wherein the pivot member comprises a pivot pin to pivotally engage to a pivot hole defined on the mounting member, and a sliding pin to slidably engage to a sliding ditch defined on the sliding member; the sliding pin slides toward a first end of the sliding ditch when the pivot member pivots in the first direction, and toward a second end of the sliding ditch when the pivot member pivots in the second direction.

3. The mounting apparatus as claimed in claim 2, wherein the sliding ditch is defined on a sliding plate of the sliding member.

4. The mounting apparatus as claimed in claim 3, wherein a retaining tab is arranged on the sliding plate; the retaining tab is slidably engaged with a retaining hole on the mounting member.

5. The mounting apparatus as claimed in claim 1, wherein the pivot member is pushed to pivot in the second direction by the hook, or by the sliding member sliding in the fourth direction; the pivot member is forced to pivot in the first direction by the sliding member sliding forced by the first resilient member in the third direction.

6. The mounting apparatus as claimed in claim 5, wherein the first resilient member is compressed when the sliding member slides in the fourth direction.

7. The mounting apparatus as claimed in claim 5, wherein the pivot member comprises a bevel sliding surface; the hook pushes the sliding surface to force the pivot member to pivot in the second direction.

8. The mounting apparatus as claimed in claim 1, wherein a pole penetrates through a first pivot hole on the mounting member and a second pivot hole on the latch member to pivotally engage the latch member to the mounting member.

9. The mounting apparatus as claimed in claim 8, wherein a second resilient member is arranged about the pole; a first end of the second resilient member abuts to the mounting member, and a second end of the second resilient member abuts to the latch member to drive the latch member away from the mounting member when the hook is released.

10. The mounting apparatus as claimed in claim 1, wherein the locking member comprises a fixing member; the first resilient member is restricted between the sliding member and the fixing member.

11. The mounting apparatus as claimed in claim 10, wherein the fixing member comprises a fixing tab to fix to a fixing hole defined on the mounting member.

12. The mounting apparatus as claimed in claim 10, wherein the first resilient member is mounted to a first pillar extended from the sliding member and a second pillar extended form the fixing member.

13. The mounting apparatus as claimed in claim 1, wherein the pivot member comprises a blocking surface to engage with the hook.

14. The mounting apparatus as claimed in claim 1, wherein the mounting member comprises a top plate, a bottom plate, a side plate, and a blocking plate; the chamber is formed between the top plate, the bottom plate, the side plate, and the blocking plate.
